(19) United States
(12) Patent Application Publication
(10) Pub. No.: US 2005/0221618 A1
(43) Pub. Date: Oct. 6, 2005

(54) System for controlling a plenum output flow geometry

(76) Inventors: Frederick J. AmRhein, Fountain Hills, AZ (US); Lewis C. Barnett, Tempe, AZ (US); Mark Alvey, Chandler, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/817,200

(22) Filed: Mar. 31, 2004

(51) Int. Cl. H01L 21/306

(52) U.S. Cl. 438/710; 438/706; 216/59; 156/345.29

(57) ABSTRACT

A flow control system disrupts a reactive flow into a process chamber in order to shape the flow geometry issuing into a substrate processing chamber. In one embodiment, gas is injected into a chamber inlet in a direction which disrupts the reactive flow traveling through the chamber inlet. In another embodiment, an insert in the chamber inlet disrupts the reactive flow traveling through the chamber inlet into the process chamber.

### BACKGROUND OF THE INVENTION

1. Field of the Invention

The present invention relates generally to deposition equipment used in semiconductor fabrication, and more specifically to controlling a reactive flow originating from a remote plasma generator.

2. Description of the Related Art

The fabrication of semiconductor products entails the deposition and etching of layers, in addition to a plurality of other types of processing. High-temperature ovens, called reactors, are used to process semiconductor substrates. For such processing, one or more substrates, such as silicon wafers, are placed on a wafer support inside the reaction chamber. The wafer(s) are then heated to a desired temperature. The wafer support, known as a susceptor, aids in absorbing radiant heat. In a typical wafer treatment step, reactant gases are passed over the heated wafer, causing the chemical vapor deposition (CVD) of a thin layer on the wafer. Various process conditions, particularly temperature uniformity and reactant gas distribution, must be carefully controlled to ensure the high quality of the resulting layers.

In the semiconductor and flat panel display fabrication industries, plasma assisted chemical reactions are often employed to aid in both the deposition and etching steps. For example, plasma generators are employed in such processes as plasma assisted or plasma enhanced chemical vapor deposition (PECVD). In PECVD, electromagnetic energy originating from a magnetron is applied to at least one precursor gas or vapor in order to transform the precursor into a more reactive species. The advantages of plasma enhanced processes include the ability to form a layer at a lower temperature and/or increase the rate of formation of a layer. Similarly, plasma energy can aid in more efficient etch reactions, either for removal of layers on a substrate (or portions thereof) or for cleaning surfaces of the deposition chamber. Because generating a reactive species in a plasma generator requires high power levels which tend to damage nearby components, it is often advantageous to generate the reactive species in a remote plasma generator, rather than in the process chamber itself. The resulting reactive species is then channeled in the form of a reactive flow to an inlet plenum which typically leads directly into the process chamber. Restrictions or obstructions typically are avoided to minimize recombination or loss of reactive species.

In providing remotely generated plasma products to a reaction chamber, it is highly advantageous to control the reactive flow in order to provide plasma products uniformly to surfaces of interest, including chamber surfaces and/or substrate surfaces.

### SUMMARY OF THE INVENTION

In accordance with one embodiment of the present invention, a method of controlling a reactive flow into a process chamber is provided comprising generating the reactive flow from a remote plasma generator and channeling the reactive flow to a chamber inlet leading to the process chamber. This reactive flow is disrupted in the chamber inlet before flowing into the process chamber.

In accordance with another preferred embodiment of the present invention, a process chamber flow control system is provided comprising a remote plasma generator configured to produce a reactive flow, a process chamber, and a flow duct connecting the remote plasma generator to the process chamber. The duct is configured to channel the reactive flow to an inlet plenum leading to the process chamber. The system includes a gas source and a gas injector configured to inject into the inlet plenum a gas from the gas source in a direction that disrupts the reactive flow.

In accordance with yet another preferred embodiment of the present invention, a method of controlling a reactive flow into a substrate process chamber is provided comprising generating a reactive flow from a remote plasma generator and channeling the reactive flow to an inlet plenum leading to a process chamber. A gas is injected into the inlet plenum at an angle selected to disrupt the reactive flow moving through the inlet plenum. The reactive flow is flowed from the inlet plenum into the substrate process chamber. Flowing the reactive flow into the substrate chamber preferably comprises both spreading the reactive flow substantially laterally across the process chamber in a direction which is substantially parallel to the wafer holder face and bending the reactive flow away from the inlet plenum so that it is substantially parallel to the wafer holder face.

In accordance with a different embodiment of the invention, a method of fabricating a substrate is provided comprising channeling a plasma generator product to a process chamber, injecting a gas in a direction which is non-parallel to a direction the plasma generator product would otherwise enter the process chamber without the non-parallel injection of the gas. This creates a combined flow of the plasma generator product and the gas into the process chamber.

In accordance with an additional embodiment of the invention, a method of controlling a reactive flow into a substrate processing chamber is provided comprising generating a plasma generator product and channeling the plasma generator product to the substrate processing chamber at an inlet mouth. An inert gas is injected from an injector prior to the inlet mouth, the inert gas being injected to be non-parallel relative to the plasma generator product. In addition, the flow rate of inert gas injected from the injector is less than the flow rate of the plasma generator product prior to the point where the gas is injected. A combined flow of the plasma generator product and the inert gas is then flowed into the substrate processing chamber.

In accordance with a further embodiment of the invention, a process chamber flow control system is provided comprising a process chamber, an inlet leading into the process chamber and a channeling duct configured to channel a plasma generator product to the inlet. An insert located in the inlet is configured to disrupt a reactive flow flowing through the inlet into the process chamber.

In accordance with yet a further embodiment of the invention, a method of controlling a reactive flow into a process chamber is provided comprising inserting a flow guide into a process chamber inlet and channeling a reactive flow from a remote plasma generator into the process chamber inlet. The reactive flow is disrupted as it flows through the flow guide into the process chamber.

A feature of the embodiments described herein is the increased ability to control a reactive flow in order to produce a more desirable flow geometry.

Another feature of certain embodiments is the increased ability to spread a reactive flow throughout a reaction chamber.

An additional feature of certain embodiments is the addition of a controlled process parameter which can be optimized separately for etch and deposition processes.

Yet another feature of certain embodiments is the control of a reactive flow geometry without the additional quartz hardware which can often be difficult to clean and polish, especially in the cramped inlet plenum.

All of these embodiments are intended to be within the scope of the invention. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIG. 1 is a schematic cross-section of a typical chemical vapor deposition (CVD) reactor incorporating a remote plasma generator and an inlet plenum to the reaction chamber, constructed in accordance with a preferred embodiment of the present invention;

FIG. 2 is a typical gas line schematic for the reactor shown in FIG. 1;

FIG. 3A is a schematic cross-section, taken along lines 3A-3A in FIG. 1;

FIG. 3B is a magnified schematic cross-section of the inlet plenum of FIG. 3A, with gas injectors configured to produce a symmetrical reactive flow issuing from the inlet plenum;

FIG. 4 is a magnified schematic cross-section of an alternate arrangement of the inlet plenum of FIG. 3, the system including gas injectors configured to inject gas parallel with the flared plenum side walls, the injectors being tuned to result in an asymmetrical reactive flow from the inlet plenum;

FIG. 5A is a schematic overhead perspective view of the inlet plenum and gas injectors of FIG. 4 showing the injectors injecting at equal flow rates (as compared with unequal flow rates shown in FIG. 4) to preferably result in a laminar flow which spreads throughout the chamber, the view taken along line 5A of FIG. 1 to further show the substrate surface relative to the reactive flow issuing from the inlet plenum;

FIG. 5B is a schematic side cross-section of the injection system shown in FIG. 5A;

FIG. 6A is a schematic plan view of a plenum insert located in the flared mouth of an inlet plenum, in accordance with a preferred embodiment;

FIG. 6B is a cross-section of the plenum insert shown in FIG. 6A taken along lines 6B-6B;

FIG. 6C is a schematic plan view of a plenum insert in accordance with another embodiment;

FIG. 6D is a schematic plan view of a plenum insert in accordance with yet another embodiment;

FIG. 6E is a cross-section of an alternate arrangement of the plenum insert shown in FIG. 6A, with the illustrated plenum insert having a smaller circumference and being mounted deeper in the inlet plenum;

FIG. 7 is a flowchart of a method of disrupting a reactive flow flowing through an inlet plenum through employing a flow guide or plenum insert, in accordance with a preferred embodiment; and

FIG. 8 is a flowchart of a method of disrupting a plenum output flow through employing gas injectors, in accordance with another preferred embodiment.

### DETAILED DESCRIPTION OF THE PREFERRED EMBODIMENT

While the preferred embodiments are presented in the context of a single-substrate, horizontal flow cold-wall reactor, it will be understood that certain aspects of the invention will have application to reactors of other types. The illustrated single-pass horizontal flow design enables the laminar flow of reactant gases with low residence times, which in turn facilitates sequential processing while minimizing reactant interaction with each other and with chamber surfaces. Thus, among other advantages, such laminar flow enables sequentially flowing reactants that might react with each other.

Prior to describing the embodiments of the invention in greater detail, a general reactor system in which embodiments of the invention can be employed is described below.

Preferred Reactor

The preferred embodiments are presented in the context of a single-substrate, horizontal flow cold-wall reactor. “Single wafer” processing tools, in general, demonstrate greater process control and uniformity than traditional batch systems, but do so at the expense of throughput, since only one or at best a handful of substrates can be processed at one time. The illustrated single-pass horizontal flow design also enables laminar flow of reactant gases, with low residence times, which in turn facilitates sequential processing while minimizing reactant interaction with each other and with chamber surfaces. Thus, among other advantages, such a laminar flow enables sequentially flowing reactants that might adversely react with each other. Reactions to be avoided include highly exothermic or explosive reactions, such as those produced by oxygen and hydrogen-bearing reactants, and reactions that produce particulate contamination of the chamber.

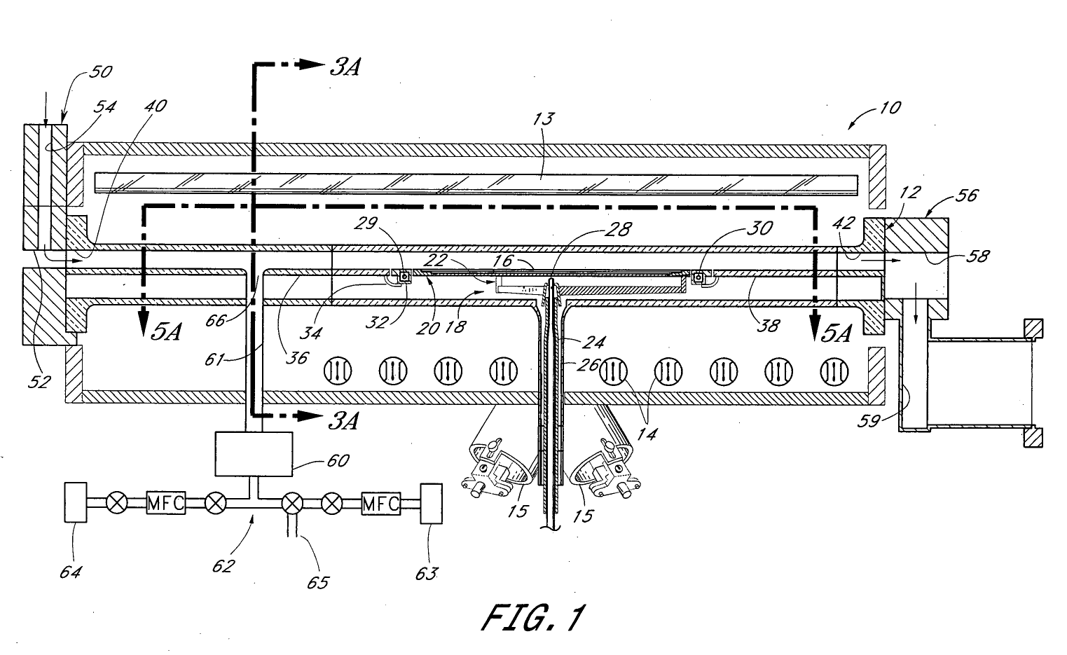

FIG. 1 shows a chemical vapor deposition (CVD) reactor 10, including a quartz process or reaction chamber 12, constructed in accordance with a preferred embodiment, and for which the methods and structures disclosed herein have particular utility. While originally designed to optimize epitaxial deposition of silicon on a single substrate at a time, the inventors have found the superior processing control of the illustrated reactor 10 to have utility in a number of different semiconductor processing steps. Moreover, the illustrated reactor 10 can safely and cleanly accomplish multiple treatment steps sequentially in the same chamber 12. The basic configuration of the reactor 10 is available commercially under the trade name Epsilon® from ASM America, Inc. of Phoenix, Ariz.

A plurality of radiant heat sources are supported outside the chamber 12 to provide heat energy in the chamber 12 without appreciable absorption by the quartz chamber 12 walls. The preferred embodiments are thus described in the context of a “cold wall” CVD reactor for processing semiconductor wafers.

The illustrated radiant heat sources comprise an upper heating assembly of elongated tube-type radiant heating elements 13, preferably disposed in spaced parallel relations and also substantially parallel with the reactant gas flow path through the chamber 12. A lower heating assembly comprises similar elongated tube-type radiant heating elements 14 below the chamber 12, preferably oriented transverse to the upper heating elements 13. Desirably, a portion of the radiant heat is diffusely reflected into the chamber 12 by rough specular reflector plates (not shown) above and below the upper and lower lamps 13, 14, respectively. Additionally, a plurality of spot lamps 15 supply concentrated heat to the underside of the substrate support structure (described below), to counteract a heat sink effect created by cold support structures extending through the bottom of the reaction chamber 12.

Each of the elongated tube type heating elements 13, 14 is preferably a high intensity tungsten filament lamp having a transparent quartz envelope containing a halogen gas, such as iodine. Such lamps produce full-spectrum radiant heat energy transmitted through the walls of the reaction chamber 12 without appreciable absorption. As is known in the art of semiconductor processing equipment, the power of the various lamps 13, 14, 15 can be controlled independently or in grouped zones in response to temperature sensors.

A workpiece or substrate, preferably comprising a silicon wafer 16, is shown supported within the reaction chamber 12 upon a substrate support structure 18. While the substrate of the illustrated embodiment is a single-crystal silicon wafer, the term “substrate” broadly refers to any surface on which a layer is to be deposited. Moreover, the principles and advantages described herein apply equally well to depositing layers over numerous other types of substrates, including, without limitation, glass substrates such as those employed in flat panel displays.

The illustrated support structure 18 includes a substrate holder or susceptor 20, upon which the wafer 16 rests, and a support spider 22. The spider 22 is mounted on a shaft 24, which extends downwardly through a tube 26 depending from the chamber lower wall. Preferably, the tube 26 communicates with a source of purge or sweep gas which can flow during processing, inhibiting process gases from escaping to the lower section of the chamber 12.

A plurality of temperature sensors are positioned in proximity to the wafer 16. The temperature sensors may take any of a variety of forms, such as optical pyrometers or thermocouples. The number and positions of the temperature sensors are selected to promote temperature uniformity. Preferably, the temperature sensors directly or indirectly sense the temperature of positions near the wafer.

In the illustrated embodiment, the temperature sensors comprise thermocouples, including a first or central thermocouple 28, suspended below the substrate holder 20 in any suitable fashion. The illustrated central thermocouple 28 passes through the spider 22 close to the wafer holder 20. The reactor 10 further includes a plurality of secondary or peripheral thermocouples, also near to the wafer 16, including a leading edge or front thermocouple 29, a trailing edge or rear thermocouple 30, and a side thermocouple (not shown). Each of the peripheral thermocouples is housed within a slip ring 32, which surrounds the substrate holder 20 and the wafer 16. Each of the central and peripheral thermocouples are connected to a temperature controller, which sets the power of the various heating elements 13, 14, 15 in response to the readings of the thermocouples.

In addition to housing the peripheral thermocouples, the slip ring 32 absorbs and emits radiant heat during high temperature processing, such that it compensates for a tendency toward greater heat loss at substrate edges, a phenomenon which is known to occur due to a greater ratio of surface area to volume in regions near such edges. By minimizing edge losses, the slip or temperature compensation ring 32 can reduce the risk of radial temperature non-uniformities across the wafer 16. The slip ring 32 can be suspended by any suitable means. For example, the illustrated slip ring 32 rests upon elbows 34 that depend from a front chamber divider 36 and a rear chamber divider 38. The dividers 36, 38 desirably are formed of quartz. In some arrangements, the rear divider 38 can be omitted.

The illustrated reaction chamber 12 includes an inlet port 40 for the injection of reactant and carrier gases, and the wafer 16 can also be received therethrough. An outlet port 42 is on the opposite side of the chamber 12, with the substrate support structure 18 positioned between the inlet 40 and the outlet 42.

An inlet component 50 is fitted to the reaction chamber 12, adapted to surround the inlet port 40, and includes a horizontally elongated slot 52 through which the wafer 16 can be inserted. A generally vertical process gas inlet 54 receives gases from remote sources, as will be described more fully below, and communicates such gases with the slot 52 and the inlet port 40. The process gas inlet 54 can include gas injectors as described in U.S. Pat. No. 5,221,556, issued to Hawkins et al., or as described with respect to FIGS. 21-26 in U.S. Pat. No. 6,093,252, issued Jul. 25, 2000, the disclosures of which are incorporated herein by reference. Such injectors are designed to maximize uniformity of gas flow for the single-wafer reactor.

An outlet component 56 similarly mounts to the process chamber 12 such that an exhaust opening 58 aligns with the outlet port 42 and leads to exhaust conduits 59. The conduits 59, in turn, can communicate with suitable vacuum means (not shown) for drawing process gases through the chamber 12. In the preferred embodiment, process gases are drawn through the reaction chamber 12 and a downstream scrubber (not shown). A pump or fan is preferably included to aid in drawing process gases through the chamber 12, and to evacuate the chamber for low pressure processing.

The reactor 10 also includes a source 60 of a reactive flow of an excited species or plasma generator product. The excited species source 60, also known as a remote generator, is preferably positioned upstream from the chamber 10. A channeling duct 61 is configured to channel reactive flow from the source 60 to a chamber inlet or inlet plenum 66 leading into the process chamber 12. The excited species source 60 of the illustrated embodiment comprises a remote plasma generator, including a magnetron power generator and an applicator along a gas line 62. An exemplary remote plasma generator is available commercially under the trade name TRW-850 from Rapid Reactive Radicals Technology (R3T) GmbH of Munich, Germany. In the illustrated embodiment, microwave energy from a magnetron is coupled to a flowing gas in an applicator along a gas line 62. A source of precursor gases 63 is coupled to the gas line 62 for introduction into the excited species generator 60. A source of carrier gas 64 is also coupled to the gas line 62. One or more further branch lines 65 can also be provided for additional reactants. As is known in the art, the gas sources 63, 64 can comprise gas tanks, bubblers, etc., depending upon the form and volatility of the reactant species. Each gas line can be provided with a separate mass flow controller (MFC) and valves, as shown, to allow selection of relative amounts of carrier and reactant species introduced to the excited species generator 60 and thence into the reaction chamber 12. The preferred processes described below employ excited species for chamber and component cleaning steps after one or more deposition cycles, and can also employ excited species for plasma assisted CVD.

Wafers are preferably passed from a handling chamber (not shown), which is isolated from the surrounding environment, through the slot 52 by a pick-up device. The handling chamber and the processing chamber 12 are preferably separated by a gate valve (not shown) of the type disclosed in U.S. Pat. No. 4,828,224, the disclosure of which is hereby incorporated herein by reference.

The total volume capacity of a single-wafer process chamber 12 designed for processing 200 mm wafers, for example, is preferably less than about 30 liters, more preferably less than about 20 liters, and most preferably less than about 10 liters. The illustrated chamber 12 has a capacity of about 7.5 liters. Because the illustrated chamber 12 is divided by the dividers 36, 38, wafer holder 20, ring 32, and the purge gas flowing from the tube 26, however, the effective volume through which process gases flow is around half the total volume (about 3.77 liters in the illustrated embodiment). Of course, it will be understood that the volume of the single-wafer process chamber 12 can be different, depending upon the size of the wafers for which the chamber 12 is designed to accommodate. For example, a single-wafer processing chamber 12 of the illustrated type, but for 300 mm wafers, preferably has a capacity of less than about 100 liters, more preferably less than about 60 liters, and most preferably less than about 30 liters. One 300 mm wafer processing chamber, commercially available from ASM America, Inc. of Phoenix, Ariz. under the trade name Epsilon 3000®, has a total volume of about 24 liters, with an effective processing gas capacity of about 11.83 liters.

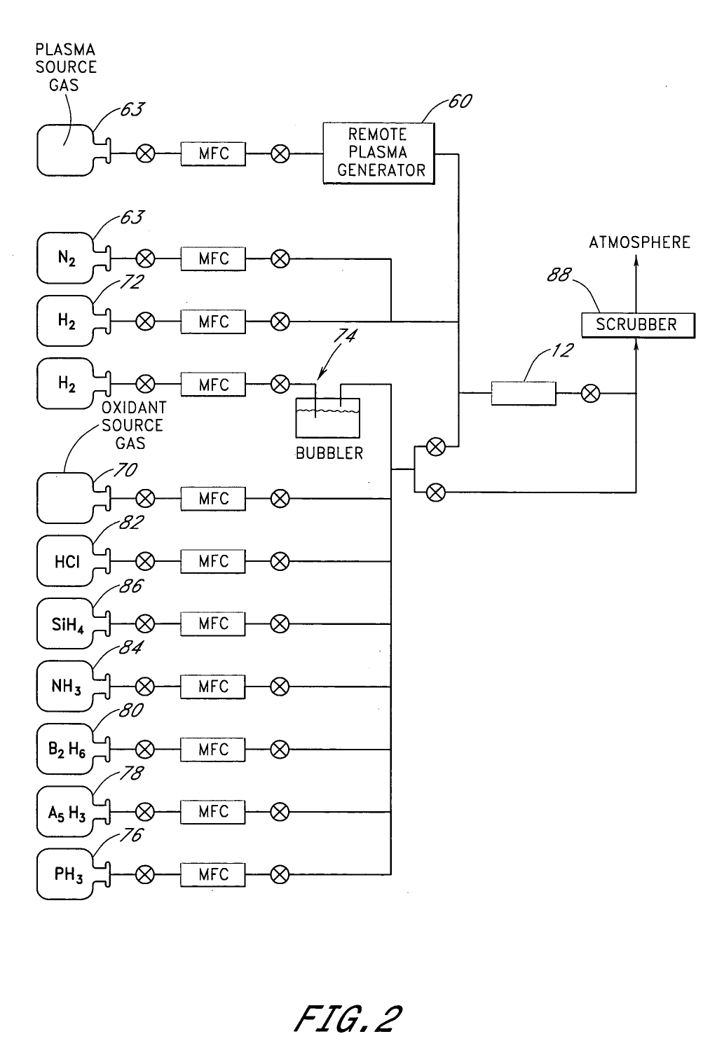

FIG. 2 shows a gas line schematic, constructed in accordance with the preferred embodiment. The reactor 10 is provided with a source 70 of oxidizing agent or oxidant. The oxidant source 70 can comprise any of a number of known oxidants, particularly a volatile oxidant such as O₂, NO, H₂O, N₂O, HCOOH, HClO₃. O₂, N₂O or NO is most preferably employed. Preferably, the oxidant is introduced in an inert carrier gas flow, such as H₂ or N₂. In other arrangements, pure reactant flows can also be used. In still other arrangements, an oxygen-containing source gas can be provided through the remote plasma generator 60 to provide excited species for oxidation. Preferably, the oxidant source gas is stored in a safe (non-explosive) mixture.

As also shown in FIG. 2, the reactor 10 further includes a source 72 of hydrogen gas (H₂). As is known in the art, hydrogen is a useful carrier gas and purge gas because it can be provided in very high purity, due to its low boiling point, and is compatible with silicon deposition. For example, H₂ is also employed in a high temperature hydrogen bake to sublimate native oxide prior to layer formation or bare silicon. H₂ can also flow through the excited species generator 60 to generate H radicals for similar surface preparation.

The preferred reactor 10 also includes a source 63 of nitrogen gas (N₂). As is known in the art, N₂ is often employed in place of H₂ as a carrier or purge gas in semiconductor fabrication. Nitrogen gas is relatively inert and compatible with many integrated materials and process flows. Other possible carrier gases include noble gases, such as helium (He) or argon (Ar).

A liquid reactant source 74 is also shown. The liquid source 74 can comprise, for example, liquid dichlorosilane (DCS), trichlorosilane (TCS), or metallorganic sources in a bubbler, and a gas line for bubbling and carrying vapor phase reactants from the bubbler to the reaction chamber 12.

The plasma gas source 63 provided through the excited species generator 60 can comprise an activated halide species. In alternate arrangements, the plasma gas source 63 can be a fluorine source gas (F), a chlorine source gas (Cl), or a combination thereof (e.g., NF₃/Cl₂,). In addition, other source gases may be employed alone or in combination with the aforementioned sources gases, as would be evident to the skilled artisan. For example, the reactive species produced can comprise fluorocarbons (e.g., C₂F₆, CF₄) or nitrogen radicals (e.g., NF₃, N₂, NO). In addition, helium (He) or argon (Ar) can be added in order to promote the lifetime of the reactive species.

Desirably, the reactor 10 will also include other source gases such as dopant sources (e.g., the illustrated phosphine 76, arsine 78 and diborane 80 sources) and etchants for cleaning the reactor walls and other internal components (e.g., HCl source 82 or NF₃/Cl₂ as the plasma gas source 63 to be provided through the excited species generator 60). While not shown, a source of germanium (e.g., germane or GeH₄) can also be provided for doping or formation of SiGe films.

Additional illustrated source gases include an ammonia (NH₃) source 84, which serves as a volatile nitrogen source, useful in CVD and nitridation anneal steps, as will be apparent from the description. A silane source 86 is also provided. As is known in the art, silanes, including monosilane (SiH₄), DCS and TCS, are common volatile silicon sources for CVD applications, such as the deposition of silicon nitride, metal silicides, and extrinsic or intrinsic silicon (polycrystalline, amorphous or epitaxial, depending upon deposition parameters). Monosilane is particularly preferred to avoid chlorine incorporation into sensitive integrated circuit structures. It should be understood that the aforementioned gases are examples of gases which can be employed with preferred embodiments. Gases different than those listed above may also be employed in preferred embodiments, as would be appreciated by the skilled artisan.

Referring back to FIG. 1, each of the gas sources may be connected to the process gas inlet 54 (FIG. 1) via gas lines with attendant safety and control valves, as well as mass flow controllers (“MFCs”), which are coordinated at a gas panel. Process gases are communicated to the process gas inlet 54 (FIG. 1) in accordance with directions programmed into a central controller and distributed into the process chamber 12 through injectors. After passing through the process chamber 12, unreacted process gases and gaseous reaction by-products are exhausted to a scrubber to condense environmentally dangerous fumes before exhausting to the atmosphere.

In addition to the conventional gas sources and liquid bubblers, discussed above, the preferred reactor 10 includes the excited species source 60 positioned remotely or upstream of the reaction chamber 12. The illustrated source 60 couples microwave energy to gas flowing in an applicator, where the gas includes reactant precursors from the reactant source 63. A plasma is ignited within the applicator, and the reactive flow of an excited species is carried toward the chamber 12. Preferably, of the excited species generated by the source 60, overly reactive ionic species substantially recombine prior to entry into the chamber 12. On the other hand, neutral radicals such as F and Cl survive to enter the chamber 12 and react as appropriate.

As will be clear from the present discussion, since energy is distributed along with the excited species, rather than solely through separate heating mechanisms, uniformity of plasma species is difficult to maintain, particularly with the illustrated upstream excited species generator 60 position. Accordingly, the preferred embodiments provide protection to the susceptor against damage during such plasma exposure.

Currently, in the industry it is generally considered disadvantageous to disturb or disrupt the reactive flow of reactive species because of the commonly held belief that the detrimental recombination of reactive species would occur at too great a frequency. However, the inventors have discovered that a controlled disruption of a reactive flow offers flow control advantages which outweigh the risk of detrimental recombination of reactive species, as described in more detail in the preferred embodiments below.

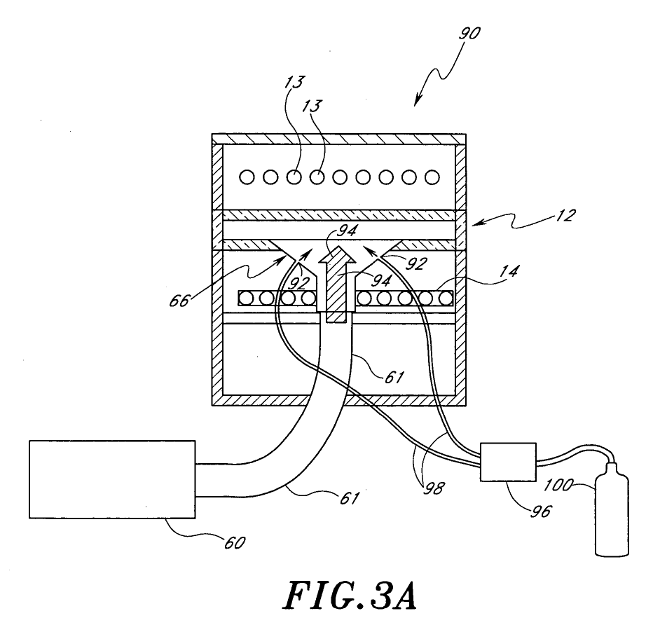

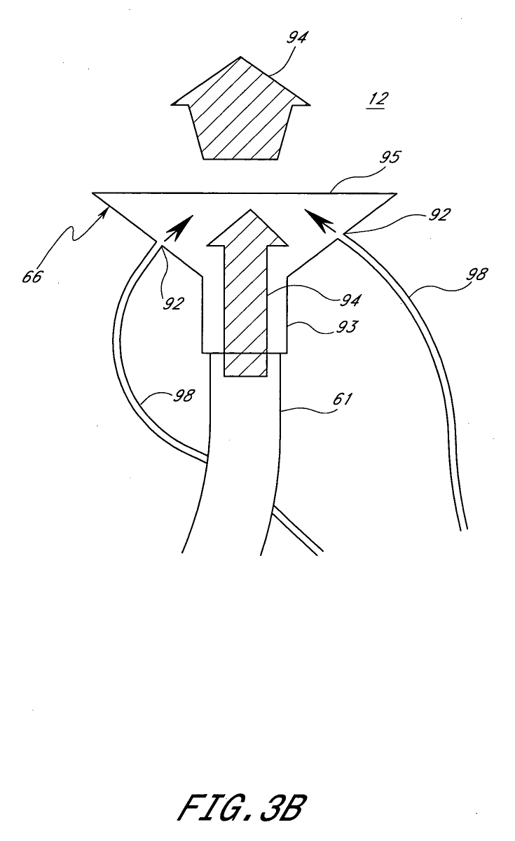

Referring to FIG. 3A, a semiconductor process system 90 is shown in which a reaction chamber 12 is joined to a remote plasma generator 60 by a channeling duct 61 or flow duct. The channeling duct 61 terminates in an inlet plenum 66 or chamber inlet leading to the interior of the chamber 12. The inlet plenum 66 is configured to channel a reactive flow 94, originating from the remote plasma generator 60 and flowed through the channeling duct 61, into the reaction chamber 12. Preferably, the inlet plenum throat 93 (FIG. 3B) and mouth 95 (FIG. 3B) are configured so the throat 93 has a smaller circumference than the mouth 95, with the inlet plenum 66 having a conical profile and side walls between the throat 93 and mouth 95. The susceptor 20 (FIG. 1), upon which a wafer 16 preferably rests, is positioned in the chamber 12 to hold the wafer 16 parallel to the inlet plenum mouth 95. On the walls of the inlet plenum 66 are gas injectors 92 which are preferably angled so that each injector 92 injects gas in a direction which is nonparallel or angled with respect to the direction the reactive flow 94 is moving as it enters the inlet plenum 66. The illustrated gas injectors 92 are configured so their direct gas flow paths intersect. Preferably, the gas injectors are configured to inject at an angle of 5° to 89° relative to the reactive flow 94, more preferably from 30° to 65°, and most preferably 40° to 55°.

Preferably, the gas injectors 92 are connected to a controller valve 96 via gas lines 98, while the controller valve 96 is connected to a gas source 100. The controller valve 96 preferably allows the gas injectors 92 to be individually tunable. The injected gas is preferably an inert gas such as nitrogen, argon, or helium. As a result of injecting gas into the inlet plenum 66 in a direction nonparallel or angled with respect to the reactive flow 94 entering the inlet plenum 66, the reactive flow 94 is disrupted as it flows through the inlet plenum 66. By altering the flow rate of the gas through each gas injector 92, the illustrated embodiment enables the tuning of the resulting flow geometry of the reactive flow 94 as it exits the inlet plenum 66 and enters chamber 12 through selecting a different reactive flow geometry than would otherwise result absent the disruption. In one preferred embodiment the gas injectors 92 are configured to disrupt the reactive flow 94 into a desired flow geometry which is advantageous for processing the substrate, while in another preferred embodiment the gas injectors 92 are configured to disrupt the reactive flow 94 into a desired flow geometry which is advantageous for cleaning the exposed surfaces within the reaction chamber 12.

In preferred embodiments, gas injectors 92 are selected to effectuate a desired reactive flow geometry issuing from the inlet plenum 66. Preferably, the gas injectors effectuate a reactive flow geometry which causes the reactive flow 94 to spread substantially laterally throughout the chamber 12. In the illustrated embodiment of FIG. 3B, the disruption of the reactive flow 94 results in a symmetrical reactive flow geometry issuing from the inlet plenum 66 when the flow rate of each respective injector 92 is equal. In one preferred embodiment, the reactive flow is only disrupted into a single geometry during a given process, i.e., the flow rate through each injection port is set at a single level which is consistent during a single process step.

In an alternative preferred embodiment the reactive flow disruption is modified from a plurality of different reactive flow geometries during a single process, i.e., the flow rate through at least one injector is dynamic during a single process step. The desired pattern can be determined in advance through empirical methods.

In certain preferred embodiments, if a symmetrical reactive flow is desired each gas injector is located about equidistant from the plenum mouth. A symmetrical plenum output flow can also be facilitated through adjusting the valve controller so as to produce gas injection flows of equal magnitude (i.e., equal velocity and volume). The skilled artisan would appreciate the balanced forces, effectuated through the manipulation of such factors as injector location, angle of injection, flow rate, etc. which can be employed in alternate arrangements to likewise result in a desired reactive flow which is symmetrical and/or spreads throughout the reaction chamber. It should be understood that, although in the preferred embodiments the injectors are shown on the flared side walls, the injectors can be located anywhere in the inlet plenum depending on the result desired, e.g. on the front and back plenum walls located between the flared side walls.

FIG. 3B shows a magnified view of the inlet plenum 66 and gas injectors 92 employed in FIG. 3A. As illustrated, the inlet plenum 66 or chamber inlet preferably has a conical profile with flared side walls on which the gas injectors 92 are located. The inlet plenum 66 has a throat 93 through which the reactive flow 94 enters the inlet plenum 66 and a mouth 95 through which the reactive flow 94 exits the inlet plenum 66. In addition, a disrupted reactive flow 94 having a geometry that is symmetrical and/or spreads throughout the reaction chamber while being spaced from the chamber sidewalls to reduce interference with the reactive flow by the sidewalls, is shown issuing from the inlet plenum 66.

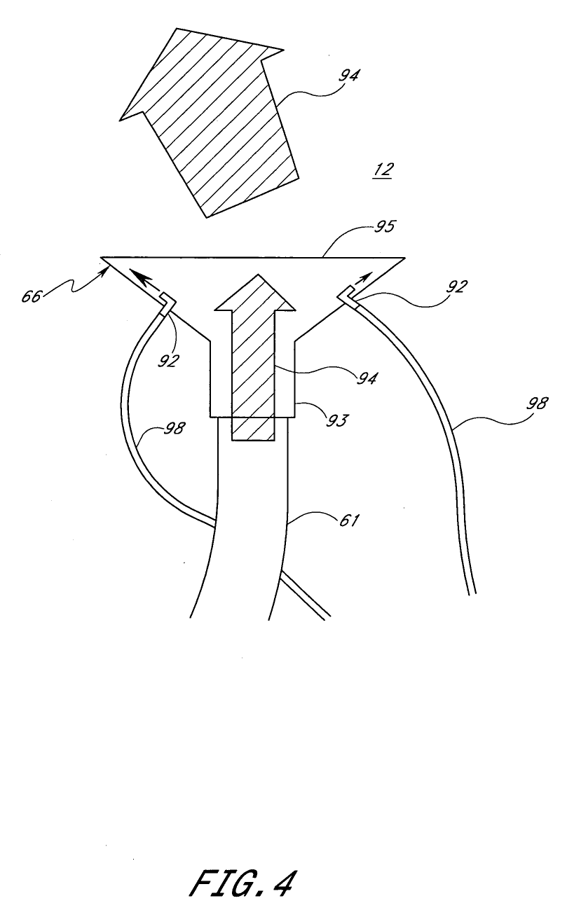

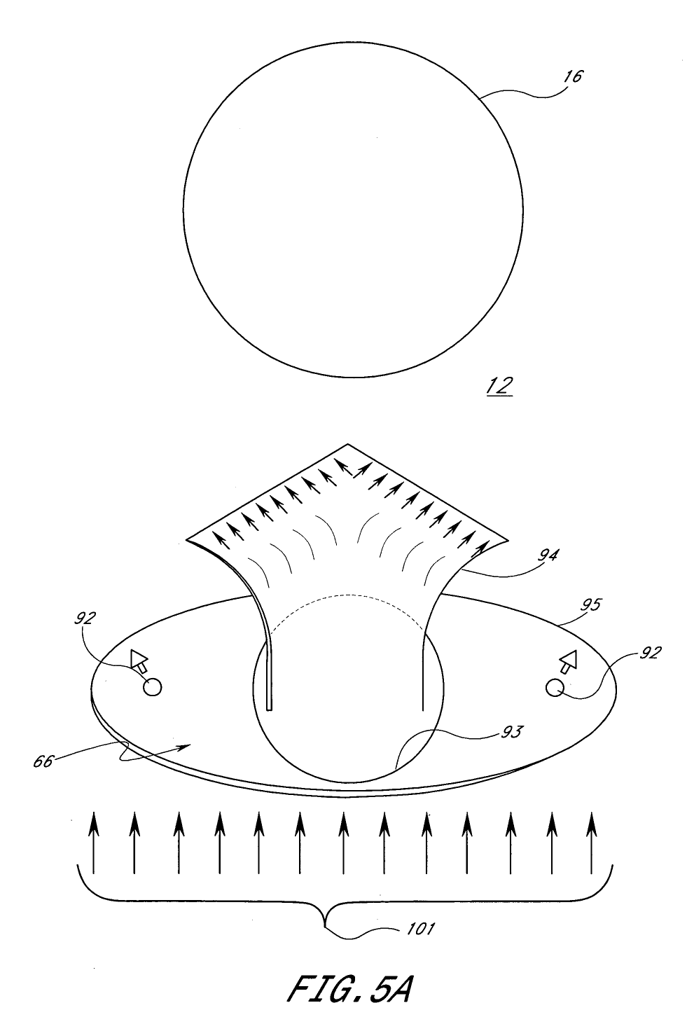

FIG. 4 illustrates another embodiment similar to the semiconductor processing system shown in FIG. 3A except that the gas injectors 92 protrude into the inlet plenum 66, each injector 92 being angled so as to inject gas in a direction substantially parallel to the respective inlet plenum 66 side walls from which the injector 92 protrudes. The illustrated gas injectors 92 are configured so their direct gas flow paths do not intersect. In addition, a higher gas injection flow is shown originating from one injector 92 as compared with a lower gas injection flow originating from the other injector 92. The relative differences in these two gas injection flows preferably result in an asymmetrical plenum outlet flow when the reactive flow 94 enters the process chamber 12. Although the gas injection flows illustrated in FIG. 4 are shown as not being equal, it should be understood that the volume and velocity of the injected gas can be tuned by adjustments to the valve controller so as to control the resulting flow geometry of the plenum output flow to produce a certain plenum output flow geometry, e.g. symmetrical or asymmetrical, depending on the needs of the process being conducted. For example, the reactive flow 94 can be disrupted to evenly spread throughout the chamber 12 through injecting gas at equal flow rates from injectors 92 evenly spaced from the inlet mouth 95, the injectors 92 being aimed to have direct injection paths within about 50° of the inlet sidewalls (See FIG. 5A). An asymmetrical plenum output flow may be effectuated by locating each gas injector 92 at different distances from the plenum mouth 95. The skilled artisan would appreciate the unbalanced forces, effectuated through the manipulation of injection port location and flow magnitude, in alternate arrangements, which would also result in an asymmetrical plenum output flow. It should be understood that the angle of the side walls relative to the throat 93 can vary from the schematic shown in FIGS. 3A-3B and 4.

In preferred arrangements of the embodiment shown in FIG. 4, the injectors are configured to inject at an angle of 91° to 150° relative to the reactive flow 94, more preferably, from 110° to 145° and, most preferably, 120° to 140°. In a preferred embodiment, the flow rate of the injected gas ranges from 0.01-4 standard liters per minute (slm) and the flow rate of the reactive flow ranges from 0.01-20 standard liters per minute (slm). In another preferred embodiment, the percentage of the flow rate of the inert gas injected from each injector ranges from 10% to 100% of the flow rate of the reactive flow from the remote plasma generator to the inlet plenum. More preferably, the percentage of the flow rate of the inert gas injected from each injector ranges from 20% to 80% of the flow rate of the reactive flow from the remote plasma generator to the inlet plenum.

Preferably, by injecting the inert gas at a flow rate equal to or less than the flow rate of the reactive flow, the geometry of the reactive flow can be slightly modified through relatively low disruption. In another preferred embodiment, in which it is desirable for the reactive flow to be highly disrupted, e.g., in order to direct flow towards areas of the chamber less accessible by the undisrupted flow, such as the chamber ceiling, floor, or sidewalls, the flow rate of the injected gas is preferably higher than the flow rate of the reactive flow. In other words, the higher the ratio of the injected inert gas flow rate to the reactive flow rate, the more extreme the disruption or direction change (i.e., relative to the direction the reactive flow would travel absent a disruption) of the reactive flow issuing into the chamber. For example, a small direction change of the reactive flow would be desirable for certain deposition processes, while a large direction change would be desirable to clean the regions of the chamber which are less accessible to the undisrupted reactive flow.

FIGS. 5A and 5B illustrate the reactive flow 94 exiting the inlet plenum 66 into the process chamber 12 substantially perpendicular to a substrate surface and then turning substantially 90 degrees to form a preferably laminar plenum output flow which is substantially parallel to the surface of the wafer 16 (or substrate) or face of the substrate holder (FIG. 1) in accordance with a preferred embodiment. The reactive flow 94 preferably enters the chamber 12 subsequently perpendicular to the non-excited chamber flow 101 or non-exited chamber flow with the reactive flow subsequently bending to be substantially parallel to the main chamber flow 101. Two gas injectors 92 are located on opposite inlet plenum 66 side walls and configured to inject a preferably inert gas at an angle to the direction which the reactive flow 94 is flowing as it travels through the inlet plenum throat 93, so as to disrupt the reactive flow 94 to spread evenly throughout the chamber 12. In addition, the non-excited flow 101 can comprise a carrier gas flow injected upstream of the point at which the reactive flow exits the inlet plenum, such as from process gas inlet 54 (FIG. 1). The gas injectors 92, which are in corresponding locations equally spaced from the plenum mouth 95, are shown injecting gas at substantially equal flow rates. However, as previously discussed, the locations and flow rates of the gas injectors 92 can be varied to effectuate a desired reactive flow geometry. For example, in an alternate embodiment, the reactive flow is directed both upstream and downstream of the inlet plenum in order to clean surfaces upstream of where the reactive flow enters the chamber.

Although the embodiments shown in the aforementioned figures employ two gas injection ports, alternate arrangements employ one gas injection port while yet other embodiments can employ three, four, or more gas injection ports.

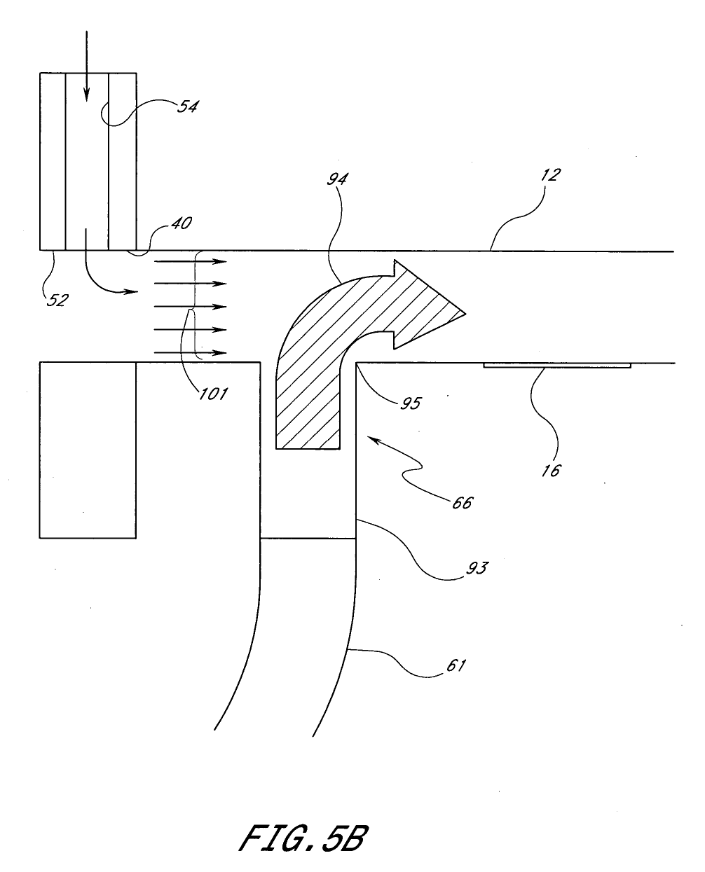

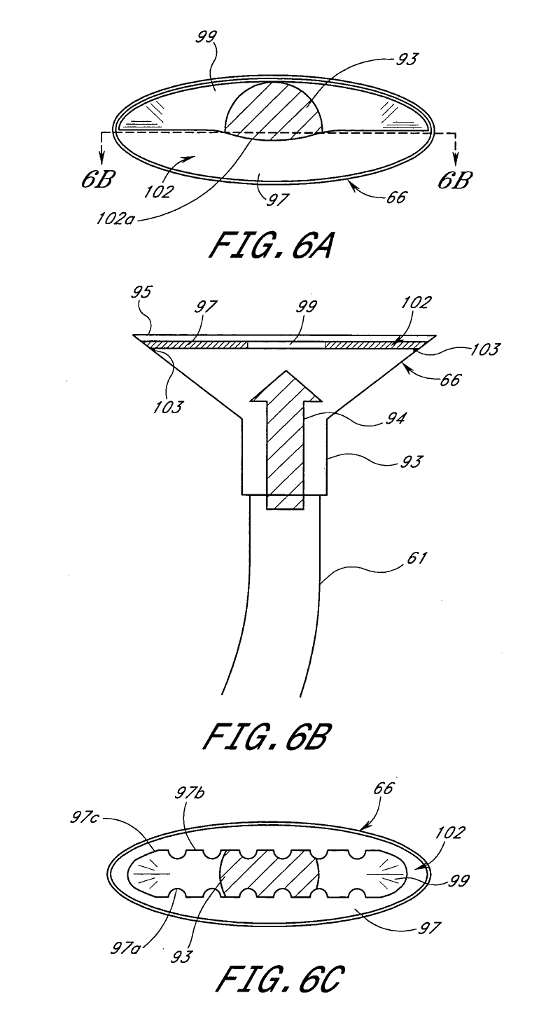

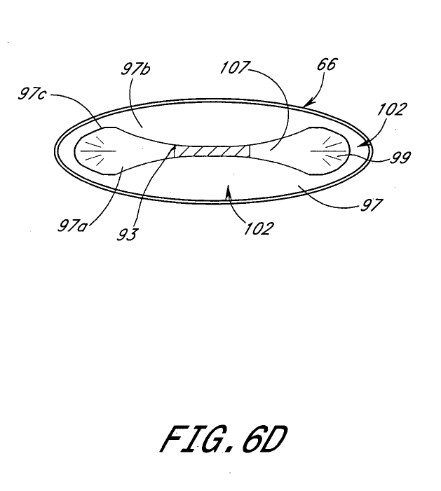

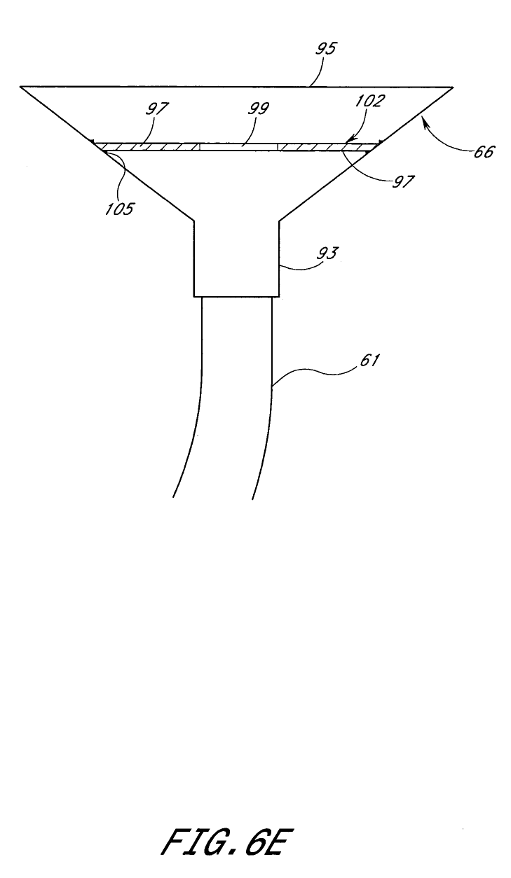

FIGS. 6A-6D illustrate preferred arrangements of a plenum insert 102 or flow guide used to control the flow geometry of the reactive flow leaving the inlet plenum 66, preferably to produce a flow geometry desirable for cleaning the process chamber 12 or for processing a substrate or wafer. The plenum insert 102 preferably comprises a thin plate having at least one flow blocking plate 97 or blocking section, and at least one shaped opening 99. The blocking plate 97 of the insert partially blocks the mouth 95 of the inlet plenum 66 and disrupts the reactive flow 94 flowing through the inlet plenum thereby modifying the reactive flow geometry issuing from the inlet plenum 66. The plenum insert 102 is preferably supported on a support 103 (e.g., tabs, shelf, or groove) inside the inlet plenum 66, as shown in FIG. 6E, or on a support 103 closer to the mouth 95 (or exit portion) of the inlet plenum, as shown in FIG. 6B.

The plenum insert 102 shown in FIGS. 6A-6B has a flow blocking plate 97 which is shaped to block about half of the plenum mouth 95 and includes a curved, shallow recess 102a in the center of the inner edge. In FIG. 6A (as well as FIGS. 6C and 6D) the portion of the mouth not blocked by the blocking plate 97 serves as an outlet for the reactive flow. Preferably, the plenum insert 102 shown in FIG. 6A serves to focus the reactive flow away from the sidewalls and towards the center of the chamber. The plenum insert 102 shown in FIG. 6C has a flow blocking plate 97 which is shaped to block the perimeter of the plenum mouth 95 (FIG. 6B) and includes a generally “race track” shaped opening 97c defined by rounded protrusions 97a which extend inwardly and are spaced by straight sections 97b. Preferably, the plenum insert shown in FIG. 6C serves to flatten the reactive flow 94, i.e., create a substantially laminar reactive flow 94 spaced from the chamber ceiling and floor.

FIG. 6D illustrate another preferred embodiment of the plenum insert 102 having an opening 107 in the shape of a “bat wing.” Preferably, the restricted center and relatively open sides serve to spread the reactive flow away from the chamber center and towards the sidewalls, e.g., to clean the sidewalls or to deposit less of a material in the center region of the wafer as compared with the outer regions.

As in prior embodiments shown in FIGS. 5A-5B (employing gas injectors rather than the plenum insert), the reactive flow issuing from the inlet plenum 66 is shaped by the plenum insert so the reactive flow has a desired flow geometry which includes bending the reactive flow about 90°. If laminar flow is desired, such as for substrate processing, a plenum insert is selected to bend the reactive flow (relative to the direction which the reactive flow 94 flows when entering the inlet plenum 66) so that the reactive flow is substantially parallel to a substrate face. Preferably, the reactive flow joins a non-excited chamber flow 101 originating from upstream of the point at which the reactive flow enters the chamber (such as originating from the process gas inlet 54 (FIG. 1)) the non-excited chamber flow 101 also moving substantially parallel to the substrate or wafer holder face. As with the gas injectors of FIGS. 4 and 5A-5B, the plenum insert 102 also preferably functions to spread the reactive flow 94 substantially laterally across the process chamber 12 in a direction substantially parallel to flow across a substrate 16 or substrate holder 20 (FIG. 1). In an alternate embodiment, when cleaning surfaces upstream of where the reactive flow enters the chamber, the reactive flow is directed both upstream and downstream of the inlet plenum.

Preferably, the inlet plenum throat 93 and mouth 95 are configured so the throat 93 has a smaller circumference than the mouth 95, with the inlet plenum 66 having a conical profile and preferably flared side walls between the throat 93 and mouth 95. In addition, preferably, the channeling duct 61 is narrower than the inlet plenum 66 which progressively widens as the inlet plenum 66 extends further from the duct 61, the mouth 95 being at least a component of the widest portion of the inlet plenum 66.

Preferably, the plenum insert 102 is located between the mouth 95 and the throat 93, e.g., as shown in FIG. 6E, in order to preferably disrupt the reactive flow 94 to a relatively greater degree. In certain preferred embodiments, the insert 102 is located proximate to mouth 95 in order to allow the cleaning of the insert 102 without having to first remove the insert 102, e.g., as shown in FIG. 6B. Preferably, the size of the plenum insert 102 is selected based on the desired mounting location, i.e., an insert 102 configured for mounting deeper in the plenum 66 (e.g., FIG. 6E) would have a smaller circumference (or perimeter) than an insert selected to be supported near the plenum mouth 95 (e.g., FIG. 6B).

Preferably, the plenum insert 102 is made of quartz and is fire polished to be smooth. In addition, although the plenum insert 102 is configured to disrupt the reactive flow in order to shape the flow geometry, the insert 102 is also preferably configured to minimize the loss of desired energetic species. In alternate embodiments, the insert is made of other materials selected to be both resistant to degradation by reactive species and easily cleaned.

The plenum insert 102 is also preferably designed to be selectively removable to allow the insert 102 to be cleaned, in order that non-disrupted reactive flow may be resumed when desired. Advantageously, the insert 102 is preferably easier to access and clean, as compared with prior art employing such structures as fins in the channeling duct. In practice, once a certain plenum insert 102 has been removed, the geometry of the reactive flow may be further modified to a different geometry by inserting another, differently configured plenum insert. For example, after deposition of a layer upon a substrate, a plenum insert 102 advantageously configured for shaping a reactive flow geometry for substrate processing can be replaced with a plenum insert 102 advantageously configured for shaping a reactive flow geometry for cleaning the exposed surfaces within the reaction chamber 12.

In one embodiment the plenum insert 102 is configured to disrupt the reactive flow into a desired flow geometry which is advantageous for processing the substrate (e.g., the insert 102 of FIGS. 6A and 6C), while in another embodiment the plenum insert 102 is configured to disrupt the reactive flow 94 into a desired flow geometry which is advantageous for cleaning the exposed surfaces within the process chamber 12 (e.g., the insert 102 of FIG. 6D).

In alternate arrangements, plenum inserts having disruption patterns other than those illustrated in FIGS. 6A, 6C, and 6D are employed to produce different flow geometries than would be produced by the illustrated inserts. For example, in an alternate embodiment, a plenum insert is employed having a centrally located circular opening with the remainder of the inlet plenum mouth being blocked by a blocking plate in order to centrally focus the resulting reactive flow. These alternate plenum inserts are also designed to disrupt the reactive flow issuing from the inlet plenum in order to control reactive flow geometry.

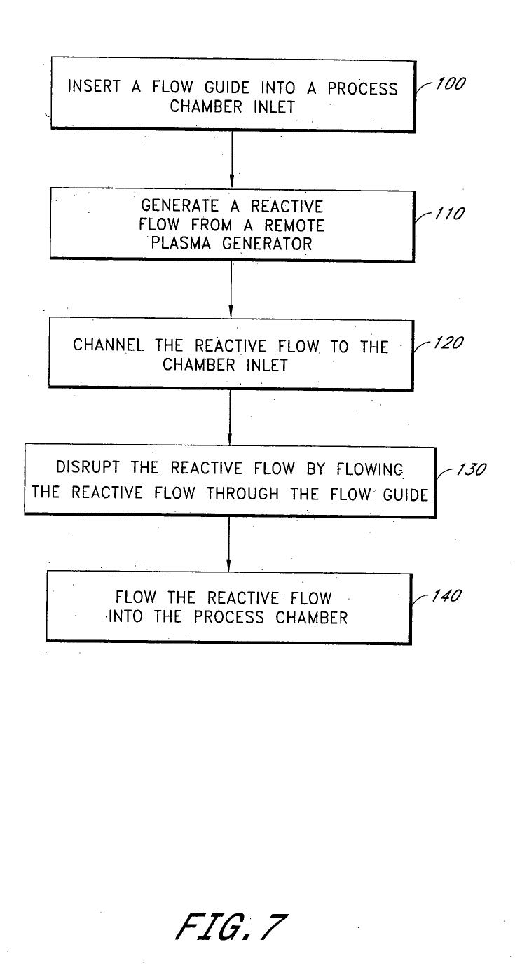

FIG. 7 shows a flow chart of a method for shaping the flow geometry of a reactive flow issuing from a chamber inlet. As a first step 100, a flow guide is inserted into the chamber inlet. When the system is ready for processing, in a second step 110 a reactive flow is generated from a remote plasma generator. In a third step 120, this reactive flow is channeled to the inlet leading to a reaction chamber. In the next step 130, the reactive flow is disrupted by flowing the reactive flow through the flow guide. As a final step 140, the reactive flow enters the reaction chamber. The disruption preferably results in the modification of the reactive flow geometry issuing from the inlet into the reaction chamber in a desired shape. The reactive flow is preferably used for processing a substrate or conditioning (e.g., cleaning, passivating, coating with catalytic material) exposed surfaces within the reaction chamber.

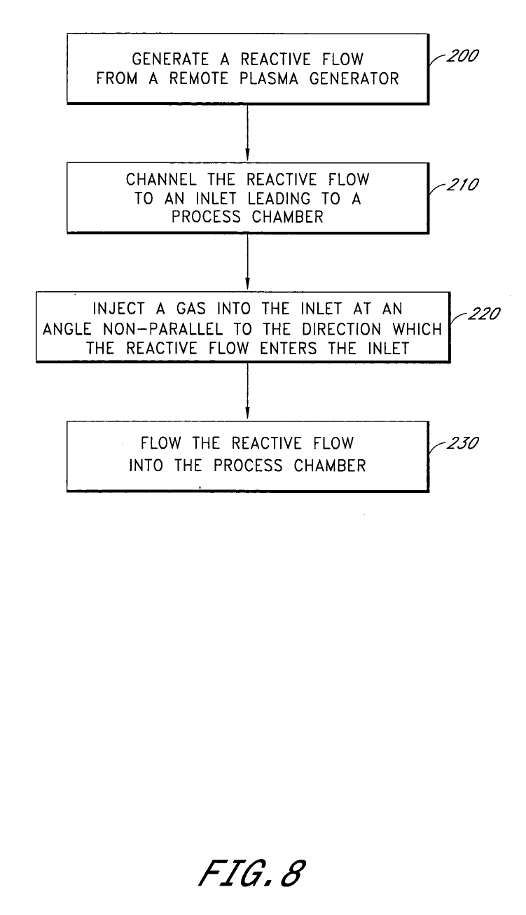

FIG. 8 shows a flow chart of a method of controlling reactive flow geometry. In a first step 200, a reactive flow is generated from a remote plasma generator, preferably prior to processing to occur in the reaction chamber, such as the processing of the substrate or conditioning of the chamber between substrates occupying the chamber. In a next step 210, reactive flow is channeled to an inlet leading to a reaction chamber. In a third step 220, a gas is injected into the inlet at an angle non-parallel to the direction in which the reactive flow enters the inlet. As a final step 230, the reactive flow enters the reaction chamber. Preferably, the angled injection of the gas serves to alter or disrupt the reactive flow into a desired flow geometry as the reactive flow enters the reaction chamber. The reactive flow can then preferably be used for such purposes as processing a substrate or conditioning exposed surfaces within the reaction chamber.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications thereof. For example, the provided injectors and plenum inserts could be combined in an alternate embodiment. Thus, it is intended that the scope of the present invention herein disclosed should not be limited by the particular disclosed embodiments described above, but should be determined only by a fair reading of the claims that follow.

1. A method of controlling a reactive flow into a process chamber comprising:
generating the reactive flow from a remote plasma generator;
channeling the reactive flow to a chamber inlet leading to the process chamber;
disrupting the reactive flow in the chamber inlet; and
flowing the disrupted reactive flow from the chamber inlet into the process chamber.

2. The method of claim 1, wherein the disrupting comprises injecting a gas into the chamber inlet at an non-parallel angle to a direction in which the reactive flow enters the chamber inlet, the gas being injected to intersect the reactive flow.

3. The method of claim 1, wherein the disrupting comprises injecting a gas into the chamber inlet at an angle non-parallel to a direction in which the reactive flow enters the chamber inlet, the gas being injected to not intersect the reactive flow.

4. The method of claim 1, wherein the disrupting comprises flowing the reactive flow through a plenum insert in the chamber inlet.

5. The method of claim 4, wherein the disrupting includes providing a plenum insert comprising a plate having at least one opening selectively located therein in order to disrupt the reactive flow issuing from the chamber inlet.

6. The method of claim 5, wherein the disrupting includes providing the plenum insert having at least one flow blocking section selected to disrupt the reactive flow as the flow exits the chamber inlet and enters the process chamber.

7. The method of claim 1, wherein the generating includes igniting a plasma in a fluorine source gas.

8. The method of claim 1, wherein the generating includes igniting a plasma in a chlorine source gas.

9. The method of claim 1, wherein the flowing includes flowing the reactive flow to clean exposed surfaces within the chamber.

10. The method of claim 1, wherein the generating includes generating a reactive flow comprising an activated halide species.

11. The method of claim 1, wherein the flowing includes processing a substrate supported in the chamber.

12. The method of claim 11, wherein the processing comprises depositing a layer onto the substrate.

13. The method of claim 1, wherein the disrupting comprises spreading the reactive flow substantially laterally across the process chamber.

14. The method of claim 13, further comprising bending the reactive flow about 90 degrees relative to the inlet so that the reactive flow is substantially parallel to a substrate surface.

15. The method of claim 14, wherein the bending comprises joining the reactive flow with a carrier gas flow upstream of the substrate surface, the carrier gas flow traveling substantially parallel to a floor and a ceiling of the chamber.

16. The method of claim 1, wherein the disrupting comprises bending the reactive flow to be non-parallel to a floor and a ceiling of the chamber.

17. The method of claim 1, wherein the flow rate of gas from the gas source into the inlet plenum is less than the flow rate of the reactive flow into the inlet plenum.

18. The method of claim 1, wherein the flow rate of gas from the gas source into the inlet plenum is greater than the flow rate of the reactive flow into the inlet plenum.

19. A process chamber flow control system comprising:
a remote plasma generator configured to produce a reactive flow;
a process chamber;
a channeling duct connecting the remote plasma generator to the process chamber, the duct being configured to channel the reactive flow from the remote plasma generator to the process chamber;
an inlet plenum between the channeling duct and the process chamber;
a gas source; and
a gas injector configured to inject into the inlet plenum a gas from the gas source in a direction which disrupts the reactive flow.

20. The system of claim 19, wherein the gas injected from the gas injector is an inert gas.

21. The system of claim 19, wherein the inlet is located upstream of a substrate holder.

22. The system of claim 19, wherein the inlet is located between a carrier gas injector and a substrate holder.

23. The system of claim 19, wherein the injector is configured to inject gas in a direction angled relative to the reactive flow flowing through the inlet plenum.

24. The system of claim 23, wherein the injector is configured to inject at an angle from 110° to 145° relative to the reactive flow.

25. The system of claim 23, wherein the injector is configured to inject at an angle of 30° to 65° relative to the reactive flow.

26. The system of claim 20, wherein the injector comprises at least two gas injectors, the injectors being configured to disrupt the reactive flow in the inlet plenum.

27. The system of claim 26, wherein at least two of the gas injectors are configured to be angled so their respective direct gas flow paths intersect.

28. The system of claim 27, wherein at least two of the gas injectors are configured to be angled so their respective direct gas flow paths intersect within the inlet plenum.

29. The system of claim 26, wherein at least two of the gas injectors are configured to be angled so their respective direct gas flow paths do not intersect within the inlet plenum.

30. The system of claim 26, wherein at least two of the gas injectors are configured to produce a symmetrical reactive flow geometry from the inlet plenum.

31. The system of claim 26, wherein at least two of the gas injectors are configured to produce an asymmetrical reactive flow geometry from the inlet plenum.

32. The system of claim 26, wherein the inlet plenum has a conical profile with flared side walls, at least two of the gas injectors being located on opposing side walls.

33. The system of claim 32, wherein the channeling duct is narrow with respect to the inlet plenum which progressively widens as the inlet plenum extends further from the duct, the inlet plenum including a mouth opening into the process chamber, the mouth being at least a component of the widest portion of the inlet plenum.

34. A method of controlling a reactive flow into a substrate process chamber comprising:
generating a reactive flow from a remote plasma generator;
channeling the reactive flow to an inlet plenum leading to a substrate process chamber;
injecting a gas into the inlet plenum at an angle selected to disrupt the reactive flow moving through the inlet plenum; and
flowing the reactive flow from the inlet plenum into the substrate process chamber.

35. The method of claim 34, wherein flowing comprises both spreading the reactive flow substantially laterally across the substrate process chamber in a direction substantially parallel to a substrate holder face and bending the reactive flow away from the inlet plenum so that the reactive flow is substantially parallel to the substrate holder face.

36. The method of claim 35, wherein the reactive flow enters the inlet plenum substantially perpendicular to a non-excited chamber flow originating from a point upstream of where the reactive flow enters the chamber and flowing the reactive flow from the inlet plenum into the substrate process chamber comprises bending the reactive flow so that the reactive flow is substantially parallel to the non-excited chamber flow.

37. The method of claim 35, wherein the injecting comprises injecting an inert gas.

38. The method of claim 34, wherein the gas is injected at a flow rate which is less than a flow rate of the reactive flow channeled from the remote plasma generator to the inlet plenum.

39. The method of claim 38, wherein the gas is injected at a flow rate ranging from 20% to 80% relative to a flow rate of the reactive flow channeled from the remote plasma generator to the inlet plenum.

40. The method of claim 34, wherein the gas is injected at a flow rate which is greater than a flow rate of the reactive flow channeled from the remote plasma generator to the inlet plenum.

41. The method of claim 34, wherein a flow rate of the gas injected into the inlet plenum is 0.01-4 standard liters per minute (slm).

42. The method of claim 41, wherein a flow rate of the reactive flow from the remote plasma generator is 0.01-20 standard liters per minute (slm).

43. A method of fabricating a substrate comprising:
channeling a plasma generator product to a process chamber;
injecting a gas in a direction which is non-parallel to a direction the plasma generator product would otherwise enter the process chamber without the non-parallel injection of the gas; and
flowing a combined flow of the plasma generator product and the gas into the process chamber.

44. The method of claim 43, wherein flowing the plasma generator product and the gas into the process chamber comprises bending the reactive flow away from the inlet plenum so that the reactive flow is substantially parallel to a substrate surface.

45. The method of claim 44, wherein flowing the plasma generator product and the gas into the process chamber further comprises spreading the reactive flow substantially laterally across the process chamber in a direction substantially parallel to the substrate surface.

46. The method of claim 45, wherein flowing further comprises flowing the combination of the plasma generator product and the gas to join a non-excited chamber flow traveling parallel to the substrate surface.

47. A method of controlling a reactive flow into a substrate processing chamber comprising:
generating a plasma generator product;
channeling the plasma generator product to an inlet mouth which is joined to the substrate processing chamber;
injecting inert gas upstream from the inlet mouth non-parallel to the plasma generator product and at a flow rate of less than the flow rate of the plasma generator product; and
flowing a combined flow of the plasma generator product and the inert gas into the substrate processing chamber.

48. A process chamber flow control system comprising:
a process chamber;
an inlet leading into the process chamber;
a channeling duct configured to channel a plasma generator product to the inlet; and
an inlet insert located in the inlet, the inlet insert being configured to disrupt a reactive flow flowing through the inlet into the process chamber.

49. The system of claim 48, further including a remote plasma generator configured to produce the plasma generator product.

50. The system of claim 48, wherein the inlet insert is configured to disrupt the plasma generator product in order to control a flow geometry of the plasma generator product flowing into the process chamber.

51. The system of claim 50, wherein the inlet insert comprises a plate having at least one shaped opening selectively located therein in order to disrupt the plasma generator product flowing through the at least one shaped opening and issuing from the inlet.

52. The system of claim 50, wherein the inlet insert comprises a plate having at least one flow blocking portion selectively located therein in order to disrupt the plasma generator product flowing around the at least one flow blocking portions and issuing from the chamber inlet.

53. The system of claim 48, wherein the inlet insert is configured to produce a uniform reactive flow geometry from the inlet.

54. The system of claim 48, wherein the inlet insert is configured to produce a non-uniform reactive flow geometry from the inlet.

55. The system of claim 48, wherein the inlet further comprises:
a throat defining the portion of the inlet where the reactive flow enters the inlet; and
a mouth defining the portion of the inlet through which the reactive flow exits the inlet into the process chamber, the mouth having a greater circumference than the throat.

56. The system of claim 55, wherein the inlet insert is located between the mouth and the throat.

57. The system of claim 55, wherein the inlet insert is located in the mouth.

58. The system of claim 57, wherein the mouth is configured to hold the inlet insert in a selectively removable position.

59. The system of claim 55, wherein the inlet has a conical profile with side walls flaring outwardly from the throat to the mouth, the flared side walls having a support configured to hold the inlet insert in a selectively removable position.

60. A method of controlling a reactive flow into a process chamber comprising:
inserting a flow guide into a process chamber inlet;
channeling a reactive flow from a remote plasma generator into the process chamber inlet; and
disrupting the reactive flow as the reactive flow flows through the flow guide into the process chamber.

61. The method of claim 60, wherein disrupting comprises shaping the flow geometry of the reactive flow into the process chamber.

62. The method of claim 61, wherein the flow guide is inserted in the exit portion of the chamber inlet.

63. The method of claim 61, wherein the flow guide is inserted between the entrance portion and the exit portion of the chamber inlet.

64. An apparatus for use in a process chamber flow control system having a process chamber, an inlet leading to the process chamber, and a channeling duct configured to channel a reactive flow to the inlet, comprising:
an inlet plate configured to disrupt a reactive flow flowing through the inlet into the process chamber.

65. The apparatus of claim 64, wherein the inlet plate comprises a plate having a flow blocking section and an opening configured to disrupt the reactive flow flowing through the opening and issuing from the inlet by altering the path of reactive flow as it flows through the inlet.
